(19) United States
(12) Patent Application Publication
(10) Pub. No.: US 2020/0017717 A1
(43) Pub. Date: Jan. 16, 2020

(54) CERIUM OXIDE ABRASIVE GRAINS

(71) Applicant: KAO CORPORATION, Tokyo (JP)

(72) Inventors: Taiki Yoshino, Wakayama (JP); Koji Kinuta, Wakayama (JP); Shin Oi, Wakayama (JP)

(73) Assignee: KAO CORPORATION, Tokyo (JP)

(21) Appl. No.: 16/475,012

(22) PCT Filed: Dec. 26, 2017
(86) PCT No.: PCT/JP2017/046538

§ 371 Date: Jun. 28, 2019

(30) Foreign Application Priority Data
Dec. 28, 2016 (JP) 2016-256275

(51) Int. Cl. C09G 1/02; C01F 17/00; C09K 3/14; B24B 37/04; H01L 21/306

(52) U.S. Cl. CPC C09G 1/02; C01F 17/0043; C09K 3/1409; B24B 37/044; H01L 21/30625; C01P 2004/03; C01P 2004/64; C01P 2004/62; C01P 2002/60; C01P 2002/54; C01P 2006/12

(57) ABSTRACT

In one aspect, the present disclosure provides cerium oxide'abrasive grains that can improve the polishing rate.

One aspect of the present disclosure relates to cerium oxide abrasive grains for use in an abrasive, in which an amount of water production in a temperature range of 300° C. or less measured using temperature-programmed reaction is 8 mmol/m² or more per unit surface area of the cerium oxide abrasive grains.

### TECHNICAL FIELD

The present disclosure relates to cerium oxide abrasive grains, a polishing liquid composition, and a semiconductor substrate production method and polishing method using the same.

### BACKGROUND ART

A chemical mechanical polishing (CMP) technique is a technique for planarizing a processing surface of a substrate to be polished by, in the state where the surface of the substrate is in contact with a polishing pad, relatively moving the substrate to be polished and the polishing pad while supplying a polishing liquid to the contact portion, thereby mechanically removing irregularities on the surface of the substrate while causing a chemical reaction.

The performance of the CMP technique is determined depending on the conditions of the CMP process, the type of polishing liquid, the type of polishing pad, and the like. Out of these factors, in particular, the polishing liquid is the factor that most significantly affects the performance of the CMP process. Silica (SiO₂) and ceria (CeO₂) are widely used as polishing particles contained in the polishing liquid.

For example, Patent Document 1 proposes, as a composite oxide that can be utilized as an abrasive, a composite oxide that contains CeO₂ and SiO₂ and has specific reduction properties.

Nowadays, in the process of producing semiconductor elements, this CMP technique is essential at the time of, e.g., planarizing an interlayer insulating film, forming a shallow trench element isolation structure (hereinafter also referred to as “element isolation structure”), and forming a plug and embedded metal wiring. In recent years, owing to dramatic improvements in terms of multilayering and definition of semiconductor elements, there is growing demand for further improvement in the yield and the throughput (production output) of the semiconductor elements. Under these circumstances, also for the CMP process, there is also a growing need for polishing that can be performed at a higher polishing rate without causing polishing flaws. For example, in the step of forming a shallow trench element isolation structure, there is demand for not only a higher polishing rate but also an improvement in polishing selectivity for a polishing stopper film (e.g., silicon nitride film) against a film to be polished (e.g., silicon oxide film) (in other words, selectivity in polishing such that the polishing stopper film is less susceptible to polishing than the film to be polished).

In particular, in technical fields relating to memories, which are used for general purposes, improvement in the throughput is an important issue, and in order to improve the throughput; abrasives are also being improved upon. For example, when ceria is used for polishing particles, a commonly known method to improve the polishing rate of a film to be polished (silicon oxide film) is to increase the particle size of the polishing particles. However, an increase in the particle size leads to an increase in polishing flaws, and this may result in reduced quality and reduction in yield.

### CITATION LIST

### Patent Document

Patent Document 1: WO 2012/165362

### DISCLOSURE OF INVENTION

### Problem to be Solved by the Invention

In recent years, in technical fields relating to semiconductors, the scale of integration is increasing, and further complication and miniaturization of wiring are required. This has led to growing demand for realization of polishing of silicon oxide films at a higher polishing rate.

The present disclosure provides cerium oxide abrasive grains that can improve the polishing rate, and a polishing liquid composition, semiconductor substrate production method, and polishing method using the same.

### Means for Solving the Problem

The present disclosure relates to cerium oxide abrasive grains for use in an abrasive, wherein an amount of water production in a temperature range of 300° C. or less measured using temperature programmed reaction is 8 mmol/m² or more per unit surface area of the cerium oxide abrasive grains.

The present disclosure relates to a polishing liquid composition containing: the cerium oxide abrasive grains according to the present disclosure; and an aqueous medium.

The present disclosure relates to a method for producing a semiconductor substrate, including the step of polishing a substrate to be polished using the polishing liquid composition according to the present disclosure.

The present disclosure relates to a method for polishing a substrate, including the step of polishing a substrate to be polished using the polishing liquid composition according to the present disclosure.

The present disclosure relates to a method for producing a semiconductor device, including the step of polishing a substrate to be polished using the polishing liquid composition according to the present disclosure.

### Effects of the Invention

The present disclosure can exhibit an effect that cerium oxide abrasive grains that can improve the polishing rate can be provided.

### BRIEF DESCRIPTION OF DRAWINGS

FIG. 1 shows an example of a scanning electron microscope (SEM) observation image of cerium oxide abrasive grains of Example 2.

### DESCRIPTION OF THE INVENTION

The inventors of the present disclosure discovered that use of cerium oxide (ceria) abrasive grains having predetermined reduction properties in polishing surprisingly can improve the polishing rate, which led to the present disclosure.

That is, the present disclosure relates to cerium oxide abrasive grains for use in an abrasive, in which the amount of water production in the temperature range of 300° C. or less measured using temperature-programmed reaction (hereinafter also referred to as “TPR”) is 8 mmol/m² or more per unit surface area of the cerium oxide abrasive grains (the cerium oxide abrasive grains are hereinafter also referred to as “the ceria abrasive grains according to the present disclosure”). The ceria abrasive grains according to the present disclosure can improve the polishing rate.

### Cerium Oxide (Ceria) Abrasive Grains

In the ceria abrasive grains according to the present disclosure, the amount of water production in the temperature range of 300° C. or less measured using TPR is 8 mmol/m² or more, preferably 9 mmol/m² or more, and more preferably 10 mmol/m² or more per unit surface area of the cerium oxide abrasive grains from the viewpoint of improving the polishing rate, and also is preferably 200 mmol/m² or less, more preferably 100 mmol/m² or less, still more preferably 80 mmol/m² or less, and yet more preferably 65 mmol/m² or less per unit surface area of the cerium oxide abrasive grains from the same viewpoint. More specifically, in the ceria abrasive grains according to the present disclosure, the amount of water production in the temperature range of 300° C. or less measured using TPR is preferably not less than 8 mmol/m² and not more than 200 mmol/m², more preferably not less than 8 mmol/m² and not more than 100 mmol/m², still more preferably not more than 8 mmol/m² and not less than 80 mmol/m², yet more preferably not less than 8 mmol/m² and not more than 65 mmol/m², even more preferably not less than 9 mmol/m² and not more than 65 mmol/m², and even more preferably not less than 10 mmol/m² and not more than 65 mmol/m² per unit surface area of the cerium oxide abrasive grains. In the present disclosure, the amount of water production by the ceria abrasive grains can be measured using the method described in the examples.

The ceria abrasive grains according to the present disclosure are preferably formed of colloidal ceria from the viewpoint of improving the polishing rate. The colloidal ceria can be obtained through the build-up process described in JP 2010-505735 A, for example.

The amount of water production can be controlled using the method described in J. Phys. Chem. B 2005, 109, pp. 24380.24385, for example. For example, the amount of water production can be controlled by changing the reduction properties by, during crystal growth in a method for producing cerium oxide having a specific crystal shape through hydrothermal treatment performed under high-concentration and highly alkaline conditions, changing the time and reaction temperature of hydrothermal treatment and the amount of an alkaline agent to be added.

The BET specific surface area of the ceria abrasive grains according to the present disclosure calculated using a nitrogen adsorption (BET) method is preferably 9.8 m²/g or more, more preferably 9.9 m²/g or more, and still more preferably 10.0 m²/g or more from the viewpoint of improving the polishing rate, and also is preferably 150 m²/g or less, more preferably 80 m²/g or less, and still more preferably 30 m²/g or less from the same viewpoint. More specifically, the BET specific surface area is preferably not less than 9.8 m²/g and not more than 150 m²/g, more preferably not less than 9.9 m²/g and not more than 150 m²/g, still more preferably not less than 10.0 m²/g and not more than 150 m²/g, yet more preferably not less than 10.0 m²/g and not more than 80 m²/g, and even more preferably not less than 10.0 m²/g and not more than 30 m²/g. In the present disclosure, the BET specific surface area can be measured using the method described in the examples.

From the viewpoint of improving the polishing rate, the average primary particle size of the ceria abrasive grains according to the present disclosure is preferably 5 nm or more, more preferably 10 nm or more, and still more preferably 20 nm or more, and also is preferably 150 nm or less, more preferably 130 nm or less, and still more preferably 100 nm or less. More specifically, the average primary particle size of the ceria abrasive grains according to the present disclosure is preferably not less than 5 nm and not more than 150 nm, more preferably not less than 5 nm and not more than 130 nm, still more preferably not less than 5 nm and not more than 100 nm, yet more preferably not less than 10 nm and not more than 100 nm, and even more preferably not less than 20 nm and not more than 100 nm. In the present disclosure, the average primary particle size of the ceria abrasive grains can be measured using the method described in the examples.

From the viewpoint of improving the polishing rate, the crystallite diameter of the ceria abrasive grains according to the present disclosure is preferably 5 nm or more, more preferably 10 nm or more, and still more preferably 15 nm or more, and also is preferably 50 nm or less, more preferably 45 nm or less, and still more preferably 40 nm or less. More specifically, the crystallite diameter of the ceria abrasive grains according to the present disclosure preferably is not less than 5 nm and not more than 50 nm, more preferably not less than 5 nm and not more than 45 nm, still more preferably not less than 5 nm and not more than 40 nm, yet more preferably not less than 10 nm and not more than 40 nm, and even more preferably not less than 15 nm and not more than 40 nm. In the present disclosure, the crystallite diameter of the ceria abrasive grains can be measured using the method described in the examples.

The ceria abrasive grains according to the present disclosure may be ceria particles composed of ceria alone, or may be composite oxide particles with some of the cerium atoms (Ce) in the cerium oxide abrasive grains being substituted with other atoms. The other atoms may be zirconium atoms (Zr), for example. That is, the ceria abrasive grains according to the present disclosure maybe, for example, composite oxide particles with some of the Ce in the ceria abrasive grains being substituted with Zr, composite oxide particles containing Ce and Zr, or composite oxide particles in which Zr is dissolved in ceria (CeO₂) crystal lattices so as to form a solid solution. When the ceria abrasive grains according to the present disclosure are the composite oxide particles with some of the Ce in the ceria abrasive grains being substituted with Zr, from the viewpoint of improving the polishing rate, the content (mol %) of Zr in the ceria abrasive grains is preferably 15 mol % or more and more preferably 20 mol % or more, and also is preferably 35 mol % or less and more preferably 30 mol % or less, with respect to the total amount of Ce and Zr (100 mol %). More specifically, the content (mol %) of Zr in the ceria abrasive grains according to the present disclosure is preferably not less than 15 mol % and not more than 35 mol % and more preferably not less than 20 mol % and not, more than 30 mol %, with respect to the total amount of Ce and Zr (100 mol %). As a method for producing the composite oxide particles, the method described in JP 2009-007543A can be employed, for example.

In one embodiment, the ceria abrasive grains according to the present disclosure do not substantially contain silicon (Si). In this case, the content (mol %) of Si in the ceria abrasive grains as expressed in terms of SiO₂ is, for example, 1 mass % or less or 0 mass %.

The shape of the ceria abrasive grains according to the present disclosure is, for example, spherical or polyhedral, and from the viewpoint of improving the polishing rate, the shape of the ceria abrasive grains is preferably a hexahedron surrounded by squares, more preferably a parallelepiped, still more preferably a cuboid, and yet more preferably a cube.

In one embodiment, the ceria abrasive grains according to the present disclosure can be used as polishing particles. Also, in another embodiment, the ceria abrasive grains according to the present disclosure can be used for polishing.

### Polishing Liquid Composition

The present disclosure relates to a polishing liquid composition containing the ceria abrasive grains according to the present disclosure and an aqueous medium (hereinafter, this polishing liquid composition is also referred to as “the polishing liquid composition according to the present disclosure”).

The content of the ceria abrasive grains in the polishing liquid composition according to the present disclosure is preferably 0.05 mass % or more, more preferably 0.1 mass % or more, and still more preferably 0.2 mass % or more from the viewpoint of improving the polishing rate, and also is preferably 10 mass % or less and more preferably 6 mass % or less from the same viewpoint. More specifically, the content of the ceria abrasive grains in the polishing liquid composition according to the present disclosure is preferably not less than 0.05 mass % and not more than 10 mass %, more preferably not less than 0.1 mass % and not more than 6 mass %, and still more preferably not less than 0.2 mass % and not more than 6 mass %.

The aqueous medium contained in the polishing liquid composition according to the present disclosure maybe, for example, water, a mixture of water and a water-soluble solvent, or the like. Examples of the water-soluble solvent include lower alcohols such as methanol, ethanol, and isopropanol, and from the viewpoint of safety in the polishing step, ethanol is preferable. From the viewpoint of improving the quality of semiconductor substrates, the aqueous medium is preferably water such as ion-exchange water, distilled water, or ultrapure water. The content of the aqueous medium in the polishing liquid composition according to the present disclosure with the total mass of the ceria abrasive grains, optional components to be described below, and the aqueous medium being 100 mass % may be the remainder of the polishing liquid composition excluding the ceria abrasive grains and the following optional components.

### Optional Components

From the viewpoint of improving the polishing rate, the polishing liquid composition of the present disclosure preferably contains, as a polishing aid, a compound having an anionic group (hereinafter also referred to simply as “compound A”).

Examples of the anionic group of the compound A include carboxylic acid groups, sulfonic acid groups, sulfuric ester groups, phosphoric ester groups, and phosphoric acid groups. These anionic groups may be in the form of neutralized salts. A counter ion when the anionic group is in the form of a salt may be a metal ion, an ammonium ion, an alkylammonium ion, or the like, and from the viewpoint of improving the quality of semiconductor substrates, the ammonium ion is preferable.

The compound A may be, for example, at least one selected from citric acid and anionic polymers. When the compound A is an anionic polymer, a specific example thereof is at least one selected from polyacrylic acids, polymethacrylic acids, polystyrene sulfonates, copolymers of a (meth)acrylic acid and a monomethoxypolyethyleneglycol mono(meth)acrylate, copolymers of a (meth)acrylate having an anionic group and a monomethoxypolyethyleneglycol mono (meth) acrylate, copolymers of an alkyl (meth)acrylate, a (meth)acrylic acid, and a monomethoxypolyethyleneglycol mono(meth)acrylate, alkali metal salts thereof, and ammonium salts thereof. From the viewpoint of improving the quality of semiconductor substrates, the anionic polymer is preferably at least one selected from polyacrylic acids and ammonium salts thereof.

From the viewpoint of improving the polishing rate, the weight-average molecular weight of the compound A is preferably 1,000 or more, more preferably 10,000 or more, and still more preferably 20,000 or more, and also is preferably 5,500,000 or less, more preferably 1,000,000 or less, and still more preferably 100,000 or less. More specifically, the weight-average molecular weight of the compound A is preferably not less than 1,000 and not more than 5,500,000, more preferably not less than 10,000 and not more than 1,000,000, and still more preferably not less than 20,000 and not more than 100,000.

In the present disclosure, the weight-average molecular weight of the compound A can be measured through gel permeation chromatography (GPC) under the following conditions using a liquid chromatograph (Hitachi, Ltd., L-6000 High Performance Liquid Chromatograph).

### <Measurement Conditions>

Detector: Shodex RI SE-61 differential refractive index detector Column: G4000PWXL and G2500PWXL (both manufactured by Tosoh Corp) connected in series were used.
Eluent: 20 μL of 0.2 M phosphate buffer solution/acetonitrile =90/10 (volume ratio) was used after adjusting the concentration thereof to 0.5 g/100 mL.
Column temperature: 40° C.
Flow rate: 1.0 mL/min
Standard polymer: monodispersed polyethylene glycol with a known molecular weight

The content of the compound Ain the polishing liquid composition according to the present disclosure is preferably 0.01 parts by mass or more, more preferably 0.05 parts by mass or more, and still more preferably 0.1 parts by mass or more with respect to 100 parts by mass of the ceria abrasive grains from the viewpoint of improving the polishing rate, and also is preferably 100 parts by mass or less, more preferably 10 parts by mass or less, and still more preferably 1 part by mass or less with respect to 100 parts by mass of the ceria abrasive grains from the same viewpoint. More specifically, the content of the compound A is preferably not less than 0.01 parts by mass and not more than 100 parts by mass, more preferably not less than 0.05 parts by mass and not less than 10 parts by mass, and still more preferably not less than 0.1 parts by mass and not more than 1 part by mass with respect to 100 parts by mass of the ceria abrasive grains.

From the viewpoint of improving the polishing rate, the content of the compound A in the polishing liquid composition according to the present disclosure is preferably 0.001 mass % or more; more preferably 0.0015 mass % or more, and still more preferably 0.0025 mass % or more, and also is preferably 1 mass % or less, more preferably 0.8 mass % or less, and still more preferably 0.6 mass % or less. More specifically, the content of the compound A is preferably not less than 0.001 mass % and not more than 1 mass %, more preferably not less than 0.0015 mass % and not more than 0.8 mass %, and still more preferably not less than 0.0025 mass % and not more than 0.6 mass %.

The polishing liquid composition according to the present disclosure may contain one or more other optional components such as a pH adjuster and polishing aids other than the compound A to the extent that the effect of the present disclosure is not impaired. From the viewpoint of ensuring an improved polishing rate, the content of the other optional component(s) in the polishing liquid composition according to the present disclosure is preferably 0.001 mass % or more, more preferably 0.0025 mass % or more, and still more preferably 0.01 mass % or more, and also is preferably 1 mass % or less, more preferably 0.5 mass % or less, and still more preferably 0.1 mass % or less. More specifically, the content of the other optional component(s) is preferably not less than 0.001 mass % and not more than 1 mass %, still more preferably not less than 0.0025 mass % and not more than 0.5 mass %, and still more preferably not less than 0.01 mass % and not more than 0.1 mass %.

The pH adjuster may be an acidic compound or an alkaline compound, for example. Examples of the acidic compound include: inorganic acids such as hydrochloric acid, nitric acid, and sulfuric acid; and organic acids such as acetic acid, oxalic acid, citric acid, and malic acid. In particular, the acidic compound is preferably at least one selected from hydrochloric acid, nitric acid, and acetic acid and more preferably at least one selected from hydrochloric acid and acetic acid in terms of their versatility. Examples of the alkaline compound include: inorganic alkaline compounds such as ammonia and potassium hydroxides; and organic alkaline compounds such as alkylamines and alkanolamines. In particular, the alkaline compound is preferably at least one selected from ammonia and alkylamines and more preferably ammonia from the viewpoint of improving the quality of semiconductor substrates.

The polishing aid other than the compound A may be an anionic surfactant other than the compound A, a nonionic surfactant, or the like. Examples of the anionic surfactant other than the compound A include alkyl ether acetates, alkyl ether phosphates, and alkyl ether sulfates. Examples of the nonionic surfactant include: nonionic polymers such as polyacrylamide; polyoxyalkylene alkyl ethers; and polyoxyethylene distyrenated phenyl ethers.

The polishing liquid composition according to the present disclosure can be produced by a production method that includes the step of blending the ceria abrasive grains according to the present disclosure, an aqueous medium, and, when desired, the above-described compound A and other optional component(s) by a known method. For example, the polishing liquid composition according to the present disclosure may be a composition obtained by blending at least the ceria abrasive grains according to the present disclosure and an aqueous medium. The term “blending” as used in the present disclosure encompasses mixing the ceria abrasive grains according to the present disclosure, an aqueous medium, and when necessary, the above-described optional component(s) either simultaneously or sequentially. The mixing order is not particularly limited. The blending may be performed using a mixer such as a homomixer, a homogenizer, an ultrasonic disperser, or a wet ball mill, for example. The amounts of the respective components to be blended in the method for producing the polishing liquid composition according to the present disclosure may be the same as the above-described contents of the respective components in the polishing liquid composition according to the present disclosure.

The polishing liquid composition according to the present disclosure may be embodied as a so-called one-pack type polishing liquid composition that is available on the market in the state where all the components are mixed beforehand, or as a so-called two-pack type polishing liquid composition adapted such that the components thereof are mixed when the polishing liquid composition is used.

From the viewpoint of improving the polishing rate, the pH of the polishing liquid composition according to the present disclosure is preferably 3 or more, more preferably 4 or more, and still more preferably 5 or more, and also is preferably 10 or less, more preferably 9 or less, and still more preferably 8 or less. More specifically, the pH of the polishing liquid composition according to the present disclosure is not less than 3 and not more than 10, more preferably not less than 4 and not more than 9, and still more preferably not less than 5 and not more than 8. In the present disclosure, the pH of the polishing liquid composition is the pH value at 25C.° , measured using a pH meter. In the present disclosure, the pH of the polishing liquid composition can be measured specifically by using the method described in the examples.

In the present disclosure, “the contents of the respective components in the polishing liquid composition” refer to the contents of the above-described respective components when the polishing liquid composition is used for polishing, i.e., at the start of using the, polishing liquid composition for polishing. The polishing liquid composition according to the present disclosure may be stored and supplied in the state of being concentrated to the extent that the stability of the polishing liquid composition is not impaired. This is preferable because the production and transportation costs can be reduced. This concentrate can be used in the polishing step after being diluted, as appropriate with the above-described aqueous medium, when necessary. The dilution ratio is preferably 5-fold to 100-fold.

An object to be polished with the polishing liquid composition according to the present disclosure may be a silicon oxide film, for example. Accordingly, the polishing liquid, composition according to the present disclosure can be used in steps that require polishing of a silicon oxide film, and can be used suitably in, for example, polishing of a silicon oxide film performed in the step of forming an element isolation structure on a semiconductor substrate, polishing of a silicon oxide film performed in the step of forming an interlayer insulating film, polishing of a silicon oxide film performed in the step of forming embedded metal wiring, polishing of a silicon oxide film performed in the step of forming an embedded capacitor, or the like.

### Polishing Liquid Kit

The present disclosure relates to a polishing liquid kit for producing a polishing liquid composition, including an abrasive grain dispersion contained in a container, in which the abrasive grain dispersion is a dispersion containing the ceria abrasive grains according to the present disclosure. The polishing liquid kit according to the present disclosure can provide a polishing liquid kit with which a polishing liquid composition that can improve the polishing rate can be prepared.

One embodiment of the polishing liquid kit according to the present disclosure is, for example, a polishing liquid kit that includes a dispersion (first liquid) containing ceria abrasive grains according to the present disclosure and an aqueous medium, and a solution (second liquid) containing, an additive(s) and an aqueous medium in a state where the first liquid, and the second liquid are not, mixed together (two-pack type polishing liquid composition). The first liquid and the second liquid are mixed together when the polishing liquid composition is used, and the thus-obtained mixture is diluted with an aqueous medium, when necessary. Examples of the additive include polishing aids, acids, oxidizing agents, heterocyclic aromatic compounds, aliphatic amine compounds, alicyclic amine compounds, and sugar compounds. The first liquid and the second liquid may each contain a pH adjuster, a thickening agent, a dispersant, a rust-preventive agent, a basic substance, a polishing rate improver, and/or the like, when necessary. The first liquid and the second liquid may be mixed together before they are supplied to a surface of an object to be polished, or they may be separately supplied to the surface of the substrate to be polished and then mixed together on the surface.

### Method for Producing Semiconductor Substrate

The present disclosure relates to a method for producing a semiconductor substrate, including the step of polishing a substrate to be polished using the polishing liquid composition according to the present disclosure (hereinafter, this step is also referred to as “the polishing step using the polishing liquid composition according to the present disclosure”) (hereinafter, this method is also referred to as “the semiconductor substrate production method according to the present disclosure”). According to the semiconductor substrate production method according to the present disclosure, the polishing rate in the polishing step can be improved by using the polishing liquid composition of the present disclosure. Therefore, the semiconductor substrate production method according to the present disclosure can exhibit an effect that the semiconductor substrate can be produced efficiently.

In one or more embodiments, the substrate to be polished may be a substrate that has a film to be polished on its surface, a substrate that has a film to be polished formed on its surface, or a substrate that has a polishing stopper film disposed under a film to be polished so as to be in contact with the film to be polished, or the like. The film to be polished may be a silicon oxide film, for example. The polishing stopper film may be a silicon nitride film or a polysilicon film. The substrate may be a semiconductor substrate, for example. The semiconductor substrate may be a silicon substrate, for example. Also, the semiconductor substrate may be a substrate formed of an elemental semiconductor such as Si or Ge, a compound semiconductor such as GaAs, TnP, or CdS, or a mixed crystal semiconductor such as InGaAs or HgCdTe.

A specific example of the semiconductor substrate production method according to the present disclosure is as follows. First, a silicon substrate is exposed to oxygen in an oxidation furnace to cause a silicon dioxide layer to grow on its surface. Then, on this silicon dioxide layer, a polishing stopper layer such as a silicon nitride (Si₃N₄) film or a polysilicon film is formed by using a CVD method (chemical vapor deposition method), for example. Next, a trench is formed using a photolithography technique on the substrate that includes the silicon substrate and the silicon nitride film disposed on one of the principal surfaces of the silicon substrate, e.g., on the substrate that has the polishing stopper layer formed on the silicon dioxide layer of the silicon substrate. Subsequently, a silicon oxide (SiO₂) film, which is a film to be polished for trench embedding, is formed using a CVD method using silane gas and oxygen gas, for example. Thus, the substrate to be polished in which the polishing stopper film is covered with the film to be polished (silicon oxide film) is obtained. As a result of forming the silicon oxide film, the trench is filled with silicon oxide of the silicon oxide film, and the surface of the polishing stopper film opposite to the surface on the silicon substrate side is covered with the silicon oxide film. The surface of the thus-formed silicon oxide film opposite to the surface on the silicon substrate side has levels formed corresponding to irregularities on the lower layer. Next, the silicon oxide film is polished by using a CMP method at least until the surface of the polishing stopper film opposite to the surface on the silicon substrate side is exposed, more preferably until the surface of the silicon oxide film is flush with the surface of the polishing stopper film. The polishing liquid composition according to the present disclosure can be used in the polishing step using this CMP method.

In the polishing according to the CMP method, irregularities on the surface of a substrate to be polished are planarized by, in the state where the surface of the substrate is in contact with a polishing pad, relatively moving the substrate to be polished and the polishing pad while supplying the polishing liquid composition according to the present disclosure to the contact portion. In the semiconductor substrate production method according to the present disclosure, another insulating film may be formed between the silicon dioxide layer and the polishing stopper film on the silicon substrate, or another insulating film may be formed between the film to be polished (e.g., silicon oxide film) and the polishing stopper film (e.g., the silicon nitride film).

In the polishing step using the polishing liquid composition according to the present disclosure, the number of revolutions of the polishing pad can be set to, for example, 30 to 200 r/min, the number of revolutions of the substrate to be polished can be set to, for example, 30 to 200 r/min, the polishing load of a polishing apparatus equipped with the polishing pad can be set to, for example, 20 to 500 g weight/cm², and the feed rate of the polishing liquid composition can be set to, for example, 10 to 500 ml/min or less. When the polishing liquid composition is a two-pack type polishing liquid composition, by adjusting the feed rate (or the feed amount) of each of the first liquid and the second liquid, it is possible to adjust the polishing rate of each of the film to be polished and the polishing stopper film and the ratio between the polishing rate of the film to be polished and the polishing rate of the polishing stopper film (polishing selectivity).

In the polishing step using the polishing liquid composition according to the present disclosure, the polishing rate of the film to be polished (e.g., silicon oxide film) is preferably 2,000 Å/min or more, more preferably 3,000 Å/min or more, and still more preferably 4,000 Å/min or more from the viewpoint of improving the productivity.

In the polishing step using the polishing liquid composition according to the present disclosure, the polishing rate of the polishing stopper film (e.g., silicon nitride film) is preferably 500 Å/ min or less, more preferably 300 Å/min or less, and still more preferably 150 Å/min or less from the viewpoint of improving the polishing selectivity and shortening the polishing time.

In the polishing step using the polishing liquid composition according to the present disclosure, the polishing rate ratio (the polishing rate of the film to be polished/the polishing rate of the polishing stopper film) is preferably 5 or more, more preferably 10 or more, still more preferably 20 or more, and yet more preferably 40 or more from the viewpoint of shortening the polishing time. The polishing selectivity in the present disclosure is synonymous with the ratio of the polishing rate of the film to be polished to the polishing rate of the polishing stopper film (the polishing rate of the film to be polished/the polishing rate of the polishing stopper film), and high polishing selectivity means that the polishing rate ratio is large.

### Polishing Method

The present disclosure relates to a method for polishing a substrate, including the step of polishing a substrate to be polished using the polishing liquid composition according to the present disclosure (hereinafter, this method is also referred to as “the polishing method according to the present disclosure”), and preferably relates to a method for polishing a substrate for use in production of a semiconductor substrate. By using the polishing method according to the present disclosure, the polishing rate in the polishing step can be improved. Therefore, the polishing method according to the present disclosure can exhibit an effect that the semiconductor substrate can be efficiently produced. In one or more embodiments, the step of polishing the substrate to be polished in the polishing method according to the present disclosure may be a step of polishing a surface of the substrate to be polished by, in the state where the surface of the substrate is in contact with a polishing pad, relatively moving the substrate and/or the polishing pad while supplying the polishing liquid composition according to the present disclosure between the substrate and the polishing pad. A specific polishing method and polishing conditions may be the same as those described above regarding the semiconductor substrate production method according to the present disclosure.

### Method for Producing Semiconductor Device

The present disclosure relates to a method for producing a semiconductor device, including the step of polishing a substrate to be polished using the polishing liquid composition according to the present disclosure (hereinafter, this method is also referred to as “the semiconductor device production method according to the present disclosure”). In one or more embodiments, the step of polishing the substrate to be polished in the semiconductor device production method according to the present disclosure is a polishing step to be performed in at least one step selected from the step of forming an element isolation structure, the step of forming an interlayer insulating film, the step of forming embedded metal wiring, and the step of forming an embedded capacitor. The semiconductor device may be, for example, a memory IC (Integrated Circuit), a logic IC, a system LSI (Large-Scale Integration), or the like.

The semiconductor device production method according to the present disclosure can exhibit an effect that a semiconductor substrate is efficiently obtained, and thus the productivity of a semiconductor device can be improved. A specific polishing method and polishing conditions in the polishing step may be the same as those described above regarding the semiconductor substrate production method according to the present disclosure.

The present disclosure further relates to the following composition and production methods.
<1> Ceria abrasive grains for use in an abrasive,
   in which an amount of water production in a temperature range of 300° C. or less measured using temperature-programmed reaction (TPR) is 8 mmol/m² or more per unit surface area of the ceria abrasive grains.
<2> The ceria abrasive grains according to <1>,
   in which the amount of water production in the temperature range of 300° C. or less measured using the TPR is 8 mmol/m² or more, preferably 9 mmol/m² or more, and more preferably 10 mmol/m² per unit surface area of the ceria abrasive grains.
<3>The ceria abrasive grains according to <1>or <2>,
   in which the amount of water production in the temperature range of 300° C. or less measured using the TPR is preferably 200 mmol/m² or less, more preferably 100 mmol/m² or less, and still more preferably 80 mmol/m² or less, and yet more preferably 65 mmol/m² or less.
<4> The ceria abrasive grains according to any one of <1>to <3>,
   in which the ceria abrasive grains are colloidal ceria.
<5> The ceria abrasive grains according to any one of <1> to <4>,
   in which a BET specific surface area of the ceria abrasive grains is preferably 9.8 m²/g or more, more preferably 9.9 m²/g or more, and still more preferably 10.0 m²/g or more.
<6> The Ceria abrasive grains according to any one of <1> to <5>,
   in which a BET specific surface area of the ceria abrasive grains is preferably 150 m²/g or less, more preferably 80 m²/g or less, and still more preferably 30 m²/g or less.
<7> The ceria abrasive grains according to any one of <1> to <6>,
   in which an average primary particle size of the ceria abrasive grains is preferably 5 nm or more, more preferably 10 nm or more, and still more preferably 20 nm or more.
<8> The ceria abrasive grains according to any one of <1> to <7>,
   in which an average primary particle size of the ceria abrasive grains is preferably 150 nm or less, more preferably 130 nm or less, and still more preferably 100 nm or less.
<9> The ceria abrasive grains according to any one of <1> to <8>,
   in which an average primary particle size of the ceria abrasive grains is not less than 5 nm and not more than 150 nm.
<10> The ceria abrasive grains according to any one of <1> to <9>,
   in which a crystallite diameter of the ceria abrasive grains is preferably 5 nm or more, more preferably 10 nm or more, and still more preferably 15 nm or more.
<11> The ceria abrasive grains according to any one of <1> to <10>,
   in which a crystallite diameter of the ceria abrasive grains is preferably 50 nm or less, more preferably 45 nm or less, and still more preferably 40 nm or less.
<12> The ceria abrasive grains according to any one of <1> to <11>,
   in which a crystallite diameter of the ceria abrasive grains is not less than 5 nm and not more than 50 nm.
<13> The ceria abrasive grains according to any one of <1> to <12>,
   in which the ceria abrasive grains are composite oxide particles with some cerium atoms (Ce) in the ceria abrasive grains being substituted with zirconium atoms (Zr).
<14> The ceria abrasive grains according to <13>,
   in which a content (mol %) of Zr in the ceria abrasive grains is preferably 15 mol % or more and more preferably 20 mol % or more with respect to a total amount of Ce and Zr (100 mol %).
<15> The ceria abrasive grains according to <13> or <14>,
   in which a content of Zr in the ceria abrasive grains is preferably 35 mol % or less and more preferably 30 mol % or less with respect to a total amount of Ce and Zr (100 mol %).
<16> The ceria abrasive grains according to any one of claims <1> to <15>,
   in which the ceria abrasive grains do not substantially contain silicon (Si), and a content of Si in the ceria abrasive grains as expressed in terms of SiO₂ is 1 mass % or less.
<17> Use of the ceria abrasive grains according to any one of <1> to <16> as polishing particles.
<18> Use of the ceria abrasive grains according to any one of <1> to <16>for polishing.
<19> A polishing liquid composition including:
   the ceria abrasive grains according to any one of <1> to <16>; and
   an aqueous medium.
<20> The polishing liquid composition according to <19>,
   in which a content of the ceria abrasive grains in the polishing liquid composition is preferably 0.05 mass % or more, more preferably 0.1 mass % or more, and still more preferably 0.2 mass % or more.
<21> The polishing liquid composition according to <19> or <20>, in which
   a content of the ceria abrasive grains in the polishing liquid composition is preferably 10 mass % or less and more preferably 6 mass % or less.
<22> The polishing liquid composition according to any one of <19> to <21>,
   in which a content of the ceria abrasive grains is not less than 0.05 mass % and not more than 10 mass %.
<23> The polishing liquid composition according to any one of <19> to <22>, further including a compound A having an anionic group.
<24> The polishing liquid composition according to <23>,
   in which a weight-average molecular weight of the compound A is preferably 1,000 or more, more preferably 10,000 or more, and still more preferably 20,000 or more.
<25> The polishing liquid composition according to <23> or <24>,
   in which a weight-average molecular weight of the compound A is preferably 5,500,000 or less, more preferably 1,000,000 or less, and still more preferably 100,000 or less.
<26> The polishing liquid composition according to any one of <23> to <25>,
   in which a content of the compound A is preferably 0.01 parts by mass or more, more preferably 0.05 parts by mass or more, and still more preferably 0.1 parts by mass with respect to 100 parts by mass of the ceria abrasive grains.
<27> The polishing liquid composition according to any one of <23> to <26>,
   in which a content of the compound A is preferably 100 parts by mass or less, more preferably 10 parts by mass or less, and still more preferably 1 part by mass or less with respect to 100 parts by mass of the ceria abrasive grains.
<28> The polishing liquid composition according to any one of <23> to <27>,
   in which a content of the compound A in the polishing liquid composition is preferably 0.001 mass % or more, more preferably 0.0015 mass % or more, and still more preferably 0.0025 mass % or more.
<29> The polishing liquid composition according to any one of <23> to <28>,
   in which a content of the compound A in the polishing liquid composition is preferably 1 mass % or less, more preferably 0.8 mass % or less, and still more preferably 0.6 mass % or less.
<30> The polishing liquid composition according to any one of <19> to <29>, further
   including at least one other optional component selected from a pH adjuster and polishing aids other than the compound A.
<31> The polishing liquid composition according to <30>,
   in which a content of the other optional component in the polishing liquid composition is preferably 0.001 mass % or more, more preferably 0.0025 mass % or more, and still more preferably 0.01 mass % or more.
<32> The polishing liquid composition according to <30> or <31>,
   in which a content of the other optional component in the polishing liquid composition is preferably 1 mass % or less, more preferably 0.5 mass % or less, and still. more preferably 0.1 mass % or less.
<33> The polishing liquid composition according to any one of <19> to <32>,
   in which a pH of the polishing liquid composition is preferably 3 or more, more preferably 4 or more, and still more preferably 5 or more.
<34> The polishing liquid composition according to any one of <19> to <33>,
   in which a pH of the polishing liquid composition is preferably 10 or less, more preferably 9 or less, and still more preferably 8 or less.
<35> The polishing liquid composition according to any one of <19> to <34>,
   in which the polishing liquid composition is used for polishing a silicon oxide film.
<36> A polishing liquid kit for producing a polishing liquid composition, the polishing liquid kit including:
   an abrasive grain dispersion contained in a container,
   wherein the abrasive grain dispersion is a dispersion containing the ceria abrasive grains according to any one, of <1> to <16>.
<37> A method for producing a semiconductor substrate, including the step of
   polishing a substrate to be polished using the polishing liquid composition according to any one of <19> to <34>.
<38> A method for polishing a substrate, including the step of
   polishing a substrate to be polished using the polishing liquid composition according to any one of <19> to <34>, which is preferably a method for polishing a substrate for use in production of a semiconductor substrate.
<39> The polishing method according to <38>,
   in which the step of polishing the substrate to be polished is a step of polishing a surface of the substrate to be polished by, in a state where the surface of the substrate is in contact with a polishing pad, relatively moving the substrate and/or the polishing pad while supplying the polishing liquid composition according to any one of <19> to <34> between the substrate and the polishing pad.
<40> A method for producing a semiconductor device, including the step of
   polishing a substrate to be polished using the polishing liquid composition according to any one of <19> to <34>.
<41> The method according to <40>,
   in which the step of polishing the substrate to be polished is a polishing step to be performed in at least one step selected from the step of forming an element isolation structure, the step of forming an interlayer insulating film, the step of forming embedded metal wiring, and the step of forming an embedded capacitor.

### EXAMPLES

Hereinafter, the present disclosure will be described in further detail by way of examples. However, these examples are merely illustrative, and the present disclosure is not limited to the following examples.

### 1. Measurement of Respective Parameters

### pH of Polishing Liquid Composition

The pH value of a polishing liquid composition at 25° C. was measured using a pH meter (DKK-TOA CORPORATION, “HM-30G”). The pH value was read from a pH meter one minute after dipping the electrode of the pH meter into the polishing liquid composition.

### Amount of Water Production in Ceria Abrasive Grains

The amount of water production in the temperature range of 300° C. or less measured using temperature-programmed reaction (TPR) was calculated in the following manner.

### <Preparation of Measurement Sample>

A ceria abrasive grain aqueous dispersion obtained by dispersing ceria abrasive grains in ion-exchange water was hot-air dried at 120° C. for 3 hours, and the obtained product was crushed in an agate mortar when necessary. In this manner, a ceria abrasive grain sample in the form of a powder was obtained. The sample thus obtained was dried at 80° C. for 3 hours. Immediately after the drying, 0.1 g of the sample was weighed and placed in a sample tube (reaction chamber).

Subsequently, pure argon gas was supplied to the reaction chamber at a flow rate of 50 cc/min. In a state where pure argon gas was supplied, the temperature of 0.1 g of the sample placed in the reaction chamber was raised from 25° C. to 300° C. at a constant temperature rise rate over 50 minutes and kept at 300° C. for 60 minutes, and the sample was allowed to cool down naturally to 100° C. and then kept at 100° C. for 10 minutes.

### <Measurement of Amount of Water Production Using Temperature-Programmed Reaction (TPR)>

Next, the amount of water production through TPR was measured under the following conditions using a temperature-programmed reaction apparatus (BEL Japan, Inc., “BELCAT-B”).

The temperature of the sample was raised from 100° C. to 950° C. while supplying a mixed gas of 5 vol % of hydrogen gas and 95 vol % of argon gas to the reaction chamber at a feed rate of 30 cc/min with a temperature rise rate being set to 5° C./min. During this temperature rise, a gas analyzer “BELMass” detected the amount of water production A (mmol/g) per unit weight resulting from reduction of tetravalent cerium to trivalent cerium in a temperature range up to 300° C. The detection of the amount of water production A was performed such that, when plotting the relationship between the amount of water production A (mmol/g) and each measurement temperature, a series of peaks indicating a water production of 5 mmol/g or more were detected as the amount of water production (mmol/g), and the amount of water production A (mmol/g) derived from the baseline was regarded as 0 mmol/g. In principle of the measurement, a plurality of amounts of water production A (mmol/g) might be observed at the same temperature. In such a case, the average value of the plurality of amounts of water production A (mmol/g) at the same temperature was regarded as the amount of water production A (mmol/g) at the measurement temperature.

Then, by dividing the detected amount of water production A (mmol/g) by the BET specific surface area B (m²/g) measured using the following BET method, the amount of water production per unit surface area A/B (mmol/m²), i.e., the amount of water production in the temperature range of 300° C. or less measured using TPR, was determined.

### BET Specific Surface Area of Ceria Abrasive Grains

A ceria abrasive grain dispersion obtained by dispersing ceria abrasive grains in ion-exchange water was hot-air dried at 120° C. for 3 hours, and the obtained product was crushed in an agate mortar when necessary. In this manner, a ceria abrasive grain sample in the form of a powder was obtained. Immediately before measuring the BET specific surface area, the sample thus obtained was dried at 120° C. for 15 minutes. Then, the BET specific surface area (m²/g) was measured using the BET method with the use of a micromeritics automatic specific surface area analyzer “FlowSorb III 2305” (Shimadzu Corporation).

### Average Primary Particle Size of Ceria Abrasive Grains

The average primary particle size (nm) of the ceria abrasive grains was calculated using the BET specific surface area obtained by the above-described BET method with the true density of the ceria particles being set to 7.2 g/cm³.

### Crystallite Diameter of Ceria Abrasive Grains

The powder of ceria abrasive grains was subjected to powder X-ray diffraction measurement, and the crystallite diameter (nm) of the ceria abrasive grains was calculated as per the Scherrer equation using the full width at half maximum of the peak of the (111) face of the ceria appearing around 29° to 30° and the diffraction angle of the ceria.

Scherrer equation: crystallite diameter (Å)=K×λ/(β×cosθ)
K: Scherrer constant, λ: X-ray wavelength=1.54056 Å, β: full width at half maximum, θ: diffraction angle 2θ/θ

### 2. Method for Producing Ceria Abrasive Grains and Details Thereof

### (1) Details of Ceria Abrasive Grains of Examples 1 to 5

As ceria abrasive grains of Examples 1 to 5, the respective types of colloidal ceria produced in the following manners were used.

### <Production Example of Ceria Abrasive Grains A1 of Example 1>

As a raw material of cerium, 0.868 g (0.002 mol) of cerium(III) nitrate hexahydrate was dissolved in 5 mL of ion-exchange water. Next, 0.014 g (0.00035 mol) of sodium hydroxide was dissolved in 35 mL of ion-exchange water (about 0.01 mol/L). The above-described cerium nitrate aqueous solution was added to this sodium hydroxide aqueous solution while being stirred, and the stirring was continued for at least 30 minutes to form a precipitate. The slurry containing the precipitate was transferred to a 50 mL Teflon® container. This Teflon® container was placed in a stainless steel reaction vessel (an autoclave manufactured by SAN-Al Kagaku Co. Ltd.), and the reaction vessel was sealed. The stainless steel container with the Teflon® container contained therein was placed in a fan dryer, and was subjected to hydrothermal treatment at 180° C. for 3 hours. After completion of the hydrothermal treatment, the mixture was cooled to room temperature. The precipitate was sufficiently washed with ion-exchange water, and then dried with a fan dryer at 100° C. As a result, a powder (ceria abrasive grains A1 of Example 1) was obtained.

X-ray diffraction confirmed that the thus-obtained powder was cerium oxide.

### <Production Example of Ceria Abrasive Grains A2 of Examples 2 and 5>

As a raw material of cerium, 0.868 g (0.002 mol) of cerium(III) nitrate hexahydrate was dissolved in 5 mL of ion-exchange water. Next, 8.5 g (0.2125 mol) of sodium hydroxide was dissolved in 35 mL of ion-exchange water (about 6 mol/L). The above-described cerium nitrate aqueous solution was added to this sodium hydroxide aqueous solution while being stirred, and the stirring was continued for at least 30 minutes to form a precipitate. The slurry containing the precipitate was transferred to a 50 mL Teflon® container. This Teflon® container was placed in a stainless steel reaction vessel (an autoclave manufactured by SAN-AI Kagaku Co. Ltd.), and the reaction vessel was sealed. The stainless steel container with the Teflon® container contained therein was placed in a fan dryer, and was subjected to hydrothermal treatment at 180° C. for 12 hours. After completion of the hydrothermal treatment, the mixture was cooled to room temperature. The precipitate was sufficiently washed with ion-exchange water, and then dried with a fan dryer at 100° C. As a result, a powder (ceria abrasive grains A2 of Examples 2 and 5) was obtained.

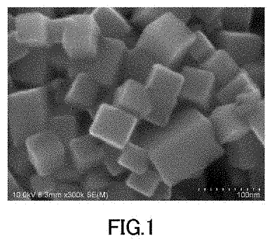

X-ray diffraction confirmed that the thus-obtained powder was cerium oxide. Further, a small amount of the powder was dispersed in ion-exchange water, and the obtained dispersion was subjected to SEM observation. As a result, it was confirmed that the thus-obtained powder was cerium oxide in a hexahedron shape surrounded by squares as shown in FIG. 1.

### <Production Example of Ceria Abrasive Grains A3 of Example 3>

Cerium oxide in a hexahedron shape surrounded by squares (ceria abrasive grains A3 of Example 3) was obtained in the same manner as in Example 2, except that the hydrothermal treatment was performed for 6 hours.

### <Production Example of Ceria Abrasive Grains A4 of Example 4>

Zirconium-containing ceria abrasive grains A4 were obtained by performing the same operations as in Example 2, except that, as the raw materials of cerium, 0.608 g (0.0014 mol) of cerium(M) nitrate hexahydrate and 0.161 g (0.0006 mol) of zirconium oxynitrate dihydrate were used.

The thus-obtained dry powder of the zirconium-containing ceria abrasive grains A4 was analyzed using X-ray diffraction. As a result, no crystal peak other than that of ceria was observed, and further, the observed peak was shifted to a higher angle side than the theoretical peak of ceria.

(2) Details of Ceria Abrasive. Grains of Comparative Examples 1 to 3

As ceria abrasive grains of Comparative Example 1, pulverized ceria B1 (Showa Denko K.K, “GPL-C1010”, average primary particle size: 67 nm, BET specific surface area: 12.2 m²/g) was used.

As ceria abrasive grains of Comparative Example 2, colloidal ceria B2 (Anan Kasei Co. Ltd., “ZENUS HC-60”, average primary particle size: 61 nm, BET specific surface area: 13.5 m²/g) was used.

As ceria abrasive grains of Comparative Example 3, colloidal ceria B3 (Anan Kasei Co. Ltd., “ZENUS HC-30”, average primary particle size: 26 nm, BET specific surface area: 31.8 m²/g) was used.

### Preparation of Polishing Liquid Compositions (Examples 1 to 5 and Comparative Examples 1 to 3)

The ceria abrasive grains of Examples 1 to 5 and Comparative Examples 1 to 3 were each mixed with an aqueous medium (ultrapure water), and a pH adjuster was added to the resultant mixtures when necessary. As a result, polishing liquid compositions of Examples 1 to 4 and Comparative Examples 1 to 3, each having a pH of 6 at 25° C., were obtained. The pH of each of the polishing liquid compositions was adjusted using ammonia. The contents of the ceria abrasive grains (mass %, active component) in the respective polishing liquid compositions are shown in Table 1.

### 4. Evaluation of Polishing Liquid Compositions (Examples 1 to 5 and Comparative Examples 1 to 3)

### Production of Test Piece

A silicon oxide film with a thickness of 2000 nm was formed on one surface of a silicon wafer using a TEOS-plasma CVD method. A 40 mm×40 mm square piece was cut out therefrom to obtain a test piece of the silicon oxide film.

### Measurement of Polishing Rate of Silicon Oxide Film (Film to be Polished)

As a polishing apparatus, “TR15M-TRK1” (Techno Rise Corporation) equipped with a platen having a diameter of 380 mm was used. As a polishing pad, a rigid urethane pad “IC-1000/Suba400” manufactured by Nitta Haas Incorporated was used. The polishing pad was attached to the platen of the polishing apparatus. The test piece was set in a holder, and the holder was placed on the polishing pad such that the surface of the test piece on which the silicon oxide film had been formed faced downward (such that the oxide film faced the polishing pad). Furthermore, a weight was placed on the holder such that a load of 300 g weight/cm² was applied to the test piece. The test piece of the silicon oxide film was polished by rotating the platen at 100 r/min and rotating the holder in the same rotation direction at 110 r/min for one minute while dropping the polishing liquid composition at a rate of 50 mL/min onto the center of the platen to which the polishing pad was attached. After the polishing, the test piece of the silicon oxide film was washed with ultrapure water, dried, and subjected to measurement using an optical interference type film thickness measuring instrument to be described below.

The thickness of the silicon oxide film was measured using the optical interference type film thickness measuring instrument (trade name: “VM-1230”, SCREEN Semiconductor Solutions Co., Ltd.) before and after the polishing. The polishing rate of the silicon oxide film was calculated using the following equation, and shown in Table 1 below.
Polishing Rate of Silicon Oxide Film (Å/min)
=[Thickness of silicon oxide film before polishing (Å)—Thickness of silicon oxide film after polishing (Å)]/Polishing time (min)

TABLE 1

| | | Ceria abrasive grains | | | | | | | | |
|---|---|---|---|---|---|---|---|---|---|---|
| | | | | Amount of water production up | | | | | Content of | |
| | | | | to 300° C. measured using TPR | | | | | abrasive | |
| | | | | Amount of | Amount of | | Average | | grains in | |
| | | | | water | water | BET | primary | | polishing | Polishing |
| | | | | production A | production per | specific | particle | Crystallite | liquid | rate |
| | | Type of abrasive | | per unit weight | unit surface | surface | size | diameter | composition | (relative |
| | | grains | | [mmol/g] | area [mmol/m²] | area [m²/g] | [nm] | [nm] | [mass %] | value) |
| Ex. | 1 | A1 | colloidal ceria | 7194 | 68.6 | 104.9 | 8 | 8 | 0.5 | 102 |
| | 2 | A2 | colloidal ceria | 175 | 10.2 | 17.2 | 48 | 34 | 0.5 | 219 |
| | 3 | A3 | colloidal ceria | 196 | 8.4 | 23.4 | 35 | 29 | 0.5 | 148 |
| | 4 | A4 | Zr-containing ceria | 192 | 10.3 | 18.7 | 44 | 33 | 0.5 | 224 |
| | | | (Zr content: 30 mol %) | | | | | | | |
| | 5 | A2 | colloidal ceria | 175 | 10.2 | 17.2 | 48 | 34 | 6.0 | 252 |
| Com. | 1 | B1 | pulverized ceria | 0 | 0.0 | 12.2 | 67 | 19 | 0.5 | 100 |
| Ex. | 2 | B2 | colloidal ceria | 0 | 0.0 | 13.5 | 61 | 38 | 0.5 | 51 |
| | 3 | B3 | colloidal ceria | 0 | 0.0 | 31.8 | 26 | 27 | 0.5 | 19 |

As can be seen in Table 1, the polishing rates achieved using the polishing liquid compositions of Examples 1 to 5, which contained the cerium oxide abrasive grains in which the amount of water production in the temperature range of 300° C. or less measured using TPR was 8 mmol/m² or more, were improved as compared with those achieved using the polishing liquid compositions of Comparative Examples 1 to 3.

### INDUSTRIAL APPLICABILITY

The polishing liquid composition according to the present disclosure is useful in a method for producing a high density or high integration semiconductor substrate.

1. Cerium oxide abrasive grains for use in an abrasive,
wherein an amount of water production in a temperature range of 300° C. or less measured using temperature-programmed reaction is 8 mmol/m² or more per unit surface area of the cerium oxide abrasive grains.

2. The cerium oxide abrasive grains according to claim 1,
wherein a BET specific surface area of the cerium oxide abrasive grains is 9.8 m²/g or more.

3. The cerium oxide abrasive grains according to claim 1,
wherein an average primary particle size of the cerium oxide abrasive grains is not less than 5 nm and not more than 150 nm.

4. The cerium oxide abrasive grains according to claim 1,
wherein a crystallite diameter of the cerium oxide abrasive grains is not less than 5 nm and not more than 50 nm.

5. The cerium oxide abrasive grains according to claim 1,
wherein the cerium oxide abrasive grains do not substantially contain silicon.

6. The cerium oxide abrasive grains according to claim 1,
wherein the cerium oxide abrasive grains are composite oxide particles with some cerium atoms in the cerium oxide abrasive grains being substituted with zirconium atoms.

7-8. (canceled)

9. A polishing liquid composition comprising:
the cerium oxide abrasive grains according to claim 1; and
an aqueous medium.

10. The polishing liquid composition according to claim 9,
wherein a content of the cerium oxide abrasive grains is not less than 0.05 mass % and not more than 10 mass %.

11. The polishing liquid composition according to claim 9,
wherein the polishing liquid composition is used for polishing a silicon oxide film.

12. A method for producing a semiconductor substrate, the method comprising the step of:
polishing a substrate to be polished using the polishing liquid composition according to claim 9.

13. A method for polishing a substrate, the method comprising the step of:
polishing a substrate to be polished using the polishing liquid composition according to claim 9.

14. A method for producing a semiconductor device, the method comprising the step of:
polishing a substrate to be polished using the polishing liquid composition according to claim 9.
